(19) United States
(12) Patent Application Publication
(10) Pub. No.: US 2002/0090095 A1
(43) Pub. Date: Jul. 11, 2002

(54) Module having integral surface acoustic wave circuits and method of manufacturing the same

(76) Inventors: James E. Flowers, Dallas, TX (US); Martin P. Goetz, Dallas, TX (US)

Correspondence Address: David H. Hitt, Hitt Gaines & Boisbrun, P.C., P.O. Box 832570, Richardson, TX, 75083, US

(21) Appl. No.: 09/755,981

(22) Filed: Jan. 5, 2001

(51) Int. Cl. H03G 5/00

(52) U.S. Cl. 381/98

(57) ABSTRACT

A module for receiving a function circuit and a method of manufacturing such module. In one embodiment, the module includes: (1) an input surface acoustic wave (SAW) circuit, located within the module and couplable to an input of the function circuit, that conditions an input signal provided to the function circuit and (2) an output SAW circuit, located within the module and couplable to an output of the function circuit, that conditions an output signal produced by the function circuit.

### TECHNICAL FIELD OF THE INVENTION

The present invention is directed, in general, to surface acoustic wave circuits and, more specifically, to a module having integral surface acoustic wave circuits and method of manufacturing the same.

### BACKGROUND OF THE INVENTION

Surface acoustic wave (SAW) devices for use in electronic signal processing have been advantageously adopted by the electronics industry. Such SAW devices have several advantages over more conventional technologies. They can be designed to provide complex signal processing in a single unit, and they also offer an additional benefit from their ability to be mass produced using semiconductor microfabrication techniques. These techniques lead to low cost devices having only small operating characteristic variations from unit to unit. Since SAW devices may be implemented in small, rugged, light-weight and power-efficient modules, they find many important applications especially in mobile, wireless and spaceborne communication systems. Such communication systems typically operate over a wide range of frequencies from about 10 megahertz to about two gigahertz. The specific signal processing capabilities and frequency range of SAW devices may be determined to allow SAW devices to perform several roles in electronic systems.

An important feature of the SAW device is its geometry, which incorporates two metal patterns having interdigitated conductive lines or traces. Such interdigitated metal structures are formed on a piezoelectric substrate and act as input and output signal paths when an AC signal voltage is applied to one of the metal structures. This AC voltage induces a surface acoustic wave in the underlying substrate wherein the acoustic wave propagates to the output structure. The interdigitated metal lines of the signal receiving portion detects the acoustic wave and converts it into a filtered electrical output signal. SAW devices, operating in the Rayleigh wave mode, can generally be designed to provide bandpass filters that achieve responses that would otherwise require several hundred inductors and capacitors in conventional LC filter designs.

This characteristic of SAW devices and their ability to be used in other circuit component applications, such as impedance matching devices, make them attractive to circuit designers. Unfortunately, the design and construction of a SAW device is not a commonly understood process, but rather requires extensive specialized knowledge, experience and manufacturing capability to be successful. Even the successful incorporation of an existing SAW device, such as a filter, into a design situation involving other circuit components makes the use of a SAW device a challenging situation. Proper mounting and placement of the SAW device is critical to its successful operation.

Accordingly, what is needed in the art is a way to enhance and facilitate the use of SAW devices when combined with additional non-SAW related circuit components.

### SUMMARY OF THE INVENTION

To address the above-discussed deficiencies of the prior art, the present invention provides a module for receiving a function circuit and a method of manufacturing such module. In one embodiment, the module includes: (1) an input surface acoustic wave (SAW) circuit, located within the module and couplable to an input of the function circuit, that conditions an input signal provided to the function circuit and (2) an output SAW circuit, located within the module and couplable to an output of the function circuit, that conditions an output signal produced by the function circuit.

The present invention therefore introduces the broad concept of bounding a function circuit (as that term is broadly defined) by SAW circuits and containing the SAW and function circuits within a single module. The SAW circuits improve the characteristics of the function circuit by conditioning the signals going into and coming out of the function circuit. Modularity allows the SAW and function circuits to be employed in various applications as though they are a single component.

In one embodiment of the present invention, the function circuit is selected from the group consisting of: (1) a power amplifier, (2) a low-noise amplifier, (3) an intermediate frequency amplifier and (4) a voltage-controlled oscillator. Those skilled in the pertinent art will understand, however, that any circuit that accepts and produces signals may find advantageous use within the module of the present invention.

In one embodiment of the present invention, the output SAW circuit impedance-matches the output signal produced by the function circuit. Of course, the output SAW circuit may perform any filtering or conditioning role.

In one embodiment of the present invention, the module further includes a common base that supports the input and output SAW circuits and the function circuit. In one embodiment to be illustrated and described, the common base includes ceramic. However, the common base may include silicon, a piezoelectric material, or any other suitable material for providing mechanical support, a substrate for formation of integrated circuitry, or both.

In one embodiment of the present invention, the module further includes a hermetic enclosure that surrounds the input and output SAW circuits and the function circuit. The hermetic enclosure advantageously isolates the SAW circuits from environmental contaminants and damage that would harm their operation.

In one embodiment of the present invention, the input and output SAW circuits are located on a common piezoelectric substrate. In a more specific embodiment of the present invention, a crosstalk shield is located between the input and output SAW circuits. Of course, the input and output SAW circuits may be located on separate piezoelectric substrates.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of a module constructed according to the principles of the present invention;

FIG. 2 illustrates a diagram of an embodiment of a module constructed according to the principles of the present invention; and

FIG. 3 illustrates a sectioned view of a circuit module showing an embodiment of the present invention.

### DETAILED DESCRIPTION

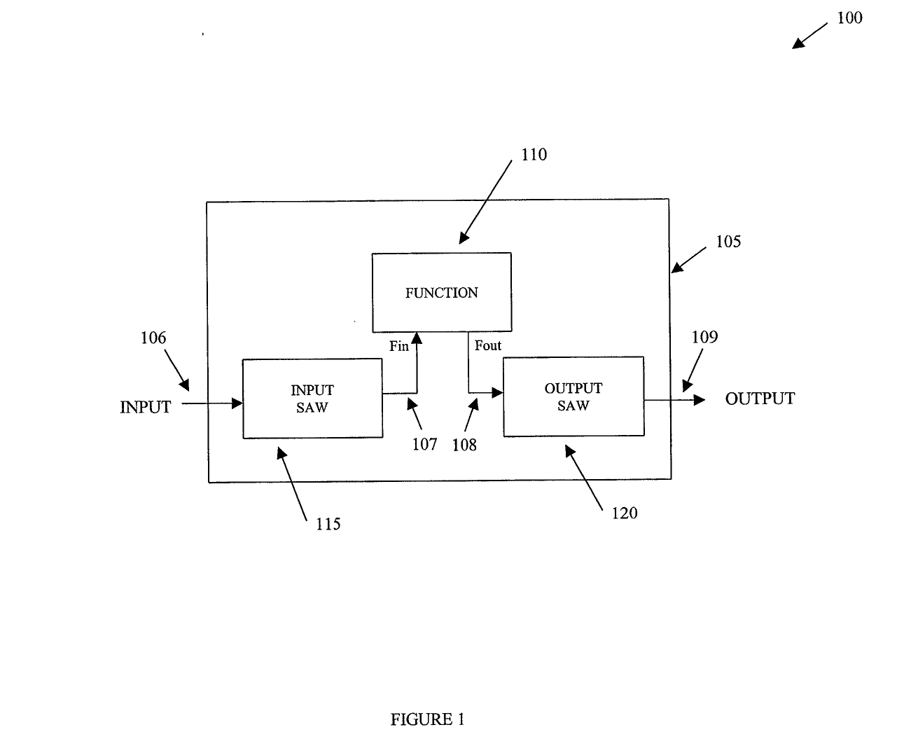

Referring initially to FIG. 1, illustrated is a block diagram of a module 100 constructed according to the principles of the present invention. The module 100 includes an enclosure 105, a function circuit 110, an input SAW circuit 115 and an output SAW circuit 120. The enclosure 105 is hermetic and surrounds the input and output SAW circuits 115, 120 and the function circuit 110.

In the illustrated embodiment, the input SAW circuit 115 is coupled between a module input 106 having a module input signal INPUT of the module 100 and an input 107 of the function circuit 110. The input SAW circuit 115 conditions the module input signal INPUT to provide a filtered form of the module input signal INPUT as an input signal Fin to the function circuit 110. The output SAW circuit 120 is similarly coupled between an output 108 of the function circuit 110 and a module output 109 having a module output signal OUPUT. The output SAW 120 conditions by impedance-matching an output signal Fout of the function circuit 110 to the requirements of the module output signal OUTPUT. Alternatively, the input and output SAW circuits 115, 120 may reverse their conditioning roles, may both provide a filtering form of conditioning or may both provide an impedance-matching form of conditioning.

The function circuit 110 is a power amplifier, in the illustrated embodiment. However, in alternative embodiments, the function circuit 110 may also be a low-noise amplifier, an intermediate frequency amplifier, a voltage-controlled oscillator or any other such circuit that would appropriately benefit from placement between the input and output SAW circuits 115, 120.

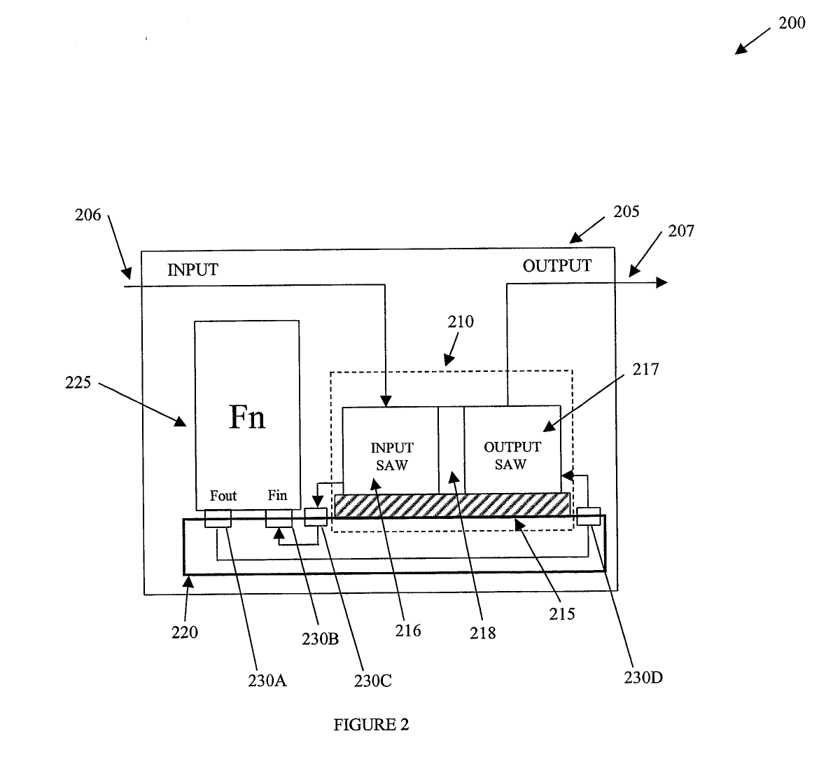

Turning now to FIG. 2, illustrated is a diagram of an embodiment of a module 200 constructed according to the principles of the present invention. The module 200 includes a hermetic enclosure 205 having a module input 206 and a module output 207, a SAW assembly 210, a common base 220 and a function circuit 225. The SAW assembly 210 includes a common piezoelectric substrate 215, an input SAW circuit 216, an output SAW circuit 217 and a crosstalk shield 218.

In the illustrated embodiment of the present invention, the module 200 provides for receiving the function circuit 225. The input SAW circuit 216 is coupled to the function circuit 225 and conditions an input signal Fin provided to the function circuit 225. The output SAW circuit 217 is also coupled to the function circuit 225 and conditions an output signal Fout produced by the function circuit 225. The input SAW circuit 216 is a bandpass filter in this embodiment, and the output SAW circuit 217 is an impedance-matching network that converts the output impedance of the function circuit 225 to a module output impedance required by the module 200.

The SAW assembly 210 and the function circuit 225, which is a low-noise amplifier in the illustrated embodiment, may be positioned on the common base 220 as shown in FIG. 2. The common base 220 contains electrical contacts, generally designated 230A-D, that provide interconnection paths from a module input signal INPUT that traverses through the various identified circuits of the module 200 to emerge as a module output signal OUTPUT.

As illustrated in FIG. 2, the input SAW circuit 216 and the output SAW circuit 217 share the common piezoelectric substrate 215. In this embodiment, the crosstalk shield 218 provides a signal isolation barrier between the input and output SAW circuits 216, 217. The crosstalk shield 218 prevents signals within each of the input and output SAW circuits 216, 217 from interfering with the other since they are in close proximity and share the common piezoelectric substrate 215.

As discussed in the embodiment of FIG. 1, the input SAW 216 filters the module input signal INPUT to provide the input signal Fin to the function circuit 225. The output SAW circuit 217 is similarly coupled between the function circuit 225 and the module output 207 to provide the module output signal OUTPUT. The output SAW circuit 217 conditions by impedance-matching the output signal Fout of the function circuit 225 to the requirements of the module output signal OUTPUT. A collection of modules constructed according to the principles of the present invention may be cascaded, as needed. Alternatively, more than one set of SAW 5 circuits and their associated function circuit may be cascaded within a single hermetic enclosure.

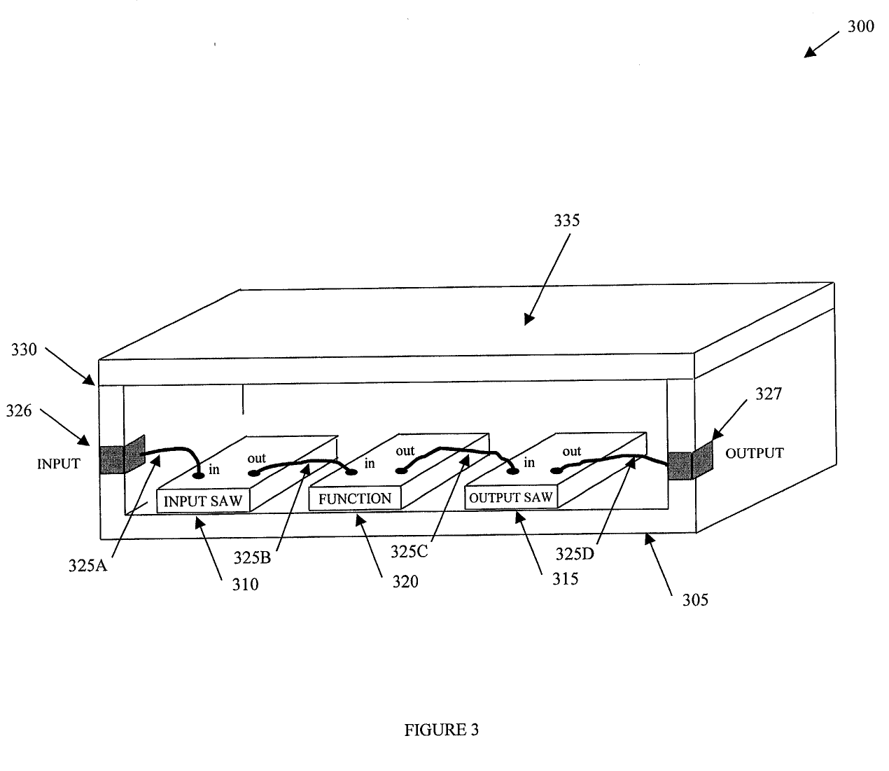

Turning now to FIG. 3, illustrated is a sectioned view of a circuit module 300 showing an embodiment of the present invention. The module 300 includes a ceramic common base 305 having a module input 326 and a module output 327, an input SAW circuit 310, an output SAW circuit 315, a function circuit 320 and a ceramic top enclosure 335 that provides a hermetic seal 330. The module 300 illustrates a method of manufacturing an embodiment of a circuit module constructed according to the principles of the present invention.

First, the ceramic common base 305 is provided. Then, the input SAW circuit and the output SAW circuit 315 are placed on the ceramic common base 305. In the illustrated embodiment of FIG. 3, input and output SAW circuits 310, 315 are formed on separate piezoelectric substrates. In an alternative embodiment, the input and output SAW circuits 310, 315 may be formed on a common piezoelectric substrate. Next, the function circuit 320 is placed on the ceramic common base 305 between the input and output SAW circuits 310, 315.

A first bond wire 325A is connected between the module input 326 and an input to the input SAW circuit 310. A second bond wire 325B is connected between an output of the input SAW circuit 310 and an input of the function circuit 320. A third bond wire 325C is connected between an output of the function circuit 320 and an input of the output circuit 315. A fourth bond wire 325D is connected between an output of the output SAW circuit 315 and the module output 327. Finally, the ceramic top enclosure 335 is placed in position on the ceramic common base 305 during appropriate ambient conditions, and the module 300 is hermetically sealed.

In summary, the present invention introduces the prevailing concept of bounding a function circuit, as that term is broadly defined, by SAW circuits and containing the SAW and function circuits within a single module. The SAW circuits improve the characteristics of the function circuit by conditioning the signals going into and coming out of the function circuit. Modularity allows the SAW and function circuits to be employed in various applications as though they are a single component.

Although the present invention has been described in detail, those skilled in the art should understand that they can make various changes, substitutions and alterations herein without departing from the spirit and scope of the invention in its broadest form.

What is claimed is:

1. A module for receiving a function circuit, comprising:
an input surface acoustic wave circuit, located within said module and couplable to an input of said function circuit, that conditions an input signal provided to said function circuit; and
an output surface acoustic wave circuit, located within said module and couplable to an output of said function circuit, that conditions an output signal produced by said function circuit.

2. The module as recited in claim 1 wherein said function circuit is selected from the group consisting of:
a power amplifier,
a low-noise amplifier,
an intermediate frequency amplifier, and
a voltage-controlled oscillator.

3. The module as recited in claim 1 wherein said output surface acoustic wave circuit impedance-matches said output signal produced by said function circuit.

4. The module as recited in claim 1 further comprising a common base that supports said input and output surface acoustic wave circuits and said function circuit.

5. The module as recited in claim 1 further comprising a hermetic enclosure that surrounds said input and output surface acoustic wave circuits and said function circuit.

6. The module as recited in claim 1 wherein said input and output surface acoustic wave circuits are located on a common piezoelectric substrate.

7. The module as recited in claim 6 wherein a crosstalk shield is located between said input and output surface acoustic wave circuits.

8. A method of manufacturing a circuit module, comprising:
providing a common base;
placing an input surface acoustic wave circuit on said common base;
placing an output surface acoustic wave circuit on said common base;
placing a function circuit on said common base;
coupling said input surface acoustic wave circuit to an input of said function circuit to allow said input surface acoustic wave circuit to condition an input signal provided to said function circuit; and
coupling said output surface acoustic wave circuit to an output of said function circuit to allow said output surface acoustic wave circuit to condition an output signal produced by said function circuit.

9. The method as recited in claim 8 wherein said function circuit is selected from the group consisting of:
a power amplifier,
a low-noise amplifier,
an intermediate frequency amplifier, and
a voltage-controlled oscillator.

10. The method as recited in claim 8 wherein said output surface acoustic wave circuit impedance-matches said output signal produced by said function circuit.

11. The method as recited in claim 8 wherein said common base comprises ceramic.

12. The method as recited in claim 8 further comprising forming a hermetic enclosure about said input and output surface acoustic wave circuits and said function circuit.

13. The method as recited in claim 8 wherein said input and output surface acoustic wave circuits are located on a common piezoelectric substrate placed on said common base.

14. The method as recited in claim 13 further comprising forming a crosstalk shield between said input and output surface acoustic wave circuits.

15. A module, comprising:
a function circuit;
an input surface acoustic wave circuit, located within said module and couplable to an input of said function circuit, that conditions an input signal provided to said function circuit;
an output surface acoustic wave circuit, located within said module and couplable to an output of said function circuit, that conditions an output signal produced by said function circuit; and
an enclosure that surrounds said input and output surface acoustic wave circuits and said function circuit.

16. The module as recited in claim 15 wherein said function circuit is selected from the group consisting of:
a power amplifier,
a low-noise amplifier,
an intermediate frequency amplifier, and
a voltage-controlled oscillator.

17. The module as recited in claim 15 wherein said output surface acoustic wave circuit impedance-matches said output signal produced by said function circuit.

18. The module as recited in claim 15 further comprising a common base that supports said input and output surface acoustic wave circuits and said function circuit.

19. The module as recited in claim 15 wherein said enclosure is hermetic.

20. The module as recited in claim 15 wherein said input and output surface acoustic wave circuits are located on a common piezoelectric substrate.

21. The module as recited in claim 20 wherein a crosstalk shield is located between said input and output surface acoustic wave circuits.
